(19) United States
(12) Patent Application Publication
(10) Pub. No.: US 2013/0082751 A1
(43) Pub. Date: Apr. 4, 2013

(54) CONTINUOUS SIGNAL GENERATOR

(71) Applicant: SAMSUNG ELECTRO-MECHANICS CO., LTD., Gyunggi-do (KR)

(72) Inventor: Soo Woong Lee, Gyeonggi-do (KR)

(73) Assignee: SAMSUNG ELECTRO-MECHANICS CO., LTD., Gyunggi-do (KR)

(21) Appl. No.: 13/624,772

(22) Filed: Sep. 21, 2012

(30) Foreign Application Priority Data
Sep. 30, 2011 (KR) 10-2011-0100219

(51) Int. Cl. H03L 7/06

(52) U.S. Cl. 327/155

(57) ABSTRACT

Disclosed herein is a continuous signal generator including: a synchronization circuit generating a synchronized clock signal; a signal source supplying a clock signal to the synchronization circuit; and a switch unit connected between the synchronization circuit and the signal source and selectively switched so as to allow the clock signal output from the signal source to be input to the synchronization circuit or feed back a clock signal output from the synchronization circuit to input the clock signal to the synchronization circuit.

### CROSS REFERENCE(S) TO RELATED APPLICATIONS

This application claims the benefit under 35 U.S.C. Section 119 of Korean Patent Application Serial No. 10-2011-0100219, entitled “Continuous Signal Generator” filed on Sep. 30, 2011, which is hereby incorporated by reference in its entirety into this application.

### BACKGROUND OF THE INVENTION

1. Technical Field

The present invention relates to a continuous signal generator, and more particularly, to a continuous signal generator converting a discontinuous signal used as an input signal source of a synchronization circuit into a continuous signal so as to be able to be used in the synchronization circuit.

2. Description of the Related Art

Clock noise of a synchronization circuit necessarily used in a phase locked loop (PLL) circuit for synchronization of a system, a clock recovery circuit, or the like, has an influence on the entire system. Therefore, it is important to generate a high purity clock. In this case, since a signal source input to the synchronization circuit should be a continuous signal having the same frequency, each of signal sources generating frequencies according to each axis generates different frequencies, such that it may not be used as an input signal source of the synchronization circuit that should be input at the same frequency.

Meanwhile, in the case in which the signal source should have a high quality factor, an external oscillator is generally used, and in the case in which the signal source needs not to have a high quality factor, an oscillator is designed and used in a system. Here, since a resonator, particularly, a micro electro mechanical system (MEMS) resonator has a quality factor significantly higher than that of a complementary metal oxide semiconductor (CMOS) oscillator in the system, in the case in which the MEMS resonator, which is a low noise signal source, may be used as a signal source in the system, the exterior oscillator needs not to be used. However, this MEMS resonator is used while repeating turn on/off of a signal with respect to any one axis according to a form thereof. In this case, an output signal of the resonator becomes a discontinuous signal with respect to each axis, such that it may not be used as an input signal source of the synchronization circuit that should be input as a continuous signal.

### SUMMARY OF THE INVENTION

An object of the present invention is to allow a signal source generating frequencies according to each axis, that is, different frequencies to be used as an input signal source of a synchronization circuit.

Another object of the present invention is that even though a signal output by a resonator used as an input signal source becomes a discontinuous signal due to repeated turn on/off, the discontinuous signal is converted into a continuous signal to be used to an input signal source of a synchronization circuit.

According to an exemplary embodiment of the present invention, there is provided a continuous signal generator including: a synchronization circuit generating a synchronized clock signal; a signal source supplying a clock signal to the synchronization circuit; and a switch unit connected between the synchronization circuit and the signal source and selectively switched so as to allow the clock signal output from the signal source to be input to the synchronization circuit or feed back a clock signal output from the synchronization circuit to input the clock signal to the synchronization circuit.

The switch unit may be switched so as to connect the signal source and the synchronization circuit to each other when the signal source outputs a continuous signal.

The switch unit may be switched so as to disconnect the signal source and the synchronization circuit from each other and feed back the clock signal output from the synchronization circuit to input the clock signal output from the synchronization circuit to the synchronization circuit, when the signal source outputs a discontinuous signal.

The switch unit may be switched so as to connect the signal source and the synchronization circuit to each other, thereby removing noise of the clock signal due to the feedback, when the signal source outputs the discontinuous signal and then outputs the continuous signal.

According to another exemplary embodiment of the present invention, there is provided a continuous signal generator including: a synchronization circuit generating a synchronized clock signal; a signal source supplying a clock signal to the synchronization circuit; a first switching element connected between the signal source and the synchronization circuit; and a second switching element selectively switched with respect to the first switching element and feeding back an output of the synchronization circuit to again input the output to the synchronization circuit.

When the first switching element is turned on, the second switching element may be turned off, and when the first switching element is turned off, the second switching element may be turned on.

The first and second switching elements may be NMOSs, when a clock signal applied to a gate of the first switching element is high, a clock signal applied to a gate of the second switching element may be low, and when the clock signal applied to the gate of the first switching element is low, the clock signal applied to the gate of the second switching element may be high.

The first and second switching elements may be PMOSs, when the clock signal applied to the gate of the first switching element is high, the clock signal applied to the gate of the second switching element may be low, and when the clock signal applied to the gate of the first switching element is low, the clock signal applied to the gate of the second switching element may be high.

The first and second switching elements may be transmission-gates in a form in which the PMOS and the NMOS are coupled in parallel with each other.

The signal source may be a MEMS resonator.

The synchronization circuit may be a synchronous mirror delay.

### BRIEF DESCRIPTION OF THE DRAWINGS

FIG. 1 is a conceptual block diagram of a continuous signal generator according to an exemplary embodiment of the present invention;

FIG. 2 is a block diagram of the continuous signal generator according to the exemplary embodiment of the present invention;

FIG. 3 is a diagram showing an output signal of a synchronization circuit according to the exemplary embodiment of the present invention for an output signal of a signal source;

FIGS. 4A to 4C are operational block diagrams of the continuous signal generator according to a period of the output signal of the signal source;

FIG. 5 is a diagram showing the continuous signal generator according to the exemplary embodiment of the present invention; and

FIG. 6 is a diagram showing a continuous signal generator according to another exemplary embodiment of the present invention.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, the present invention will be described with the accompanying drawings.

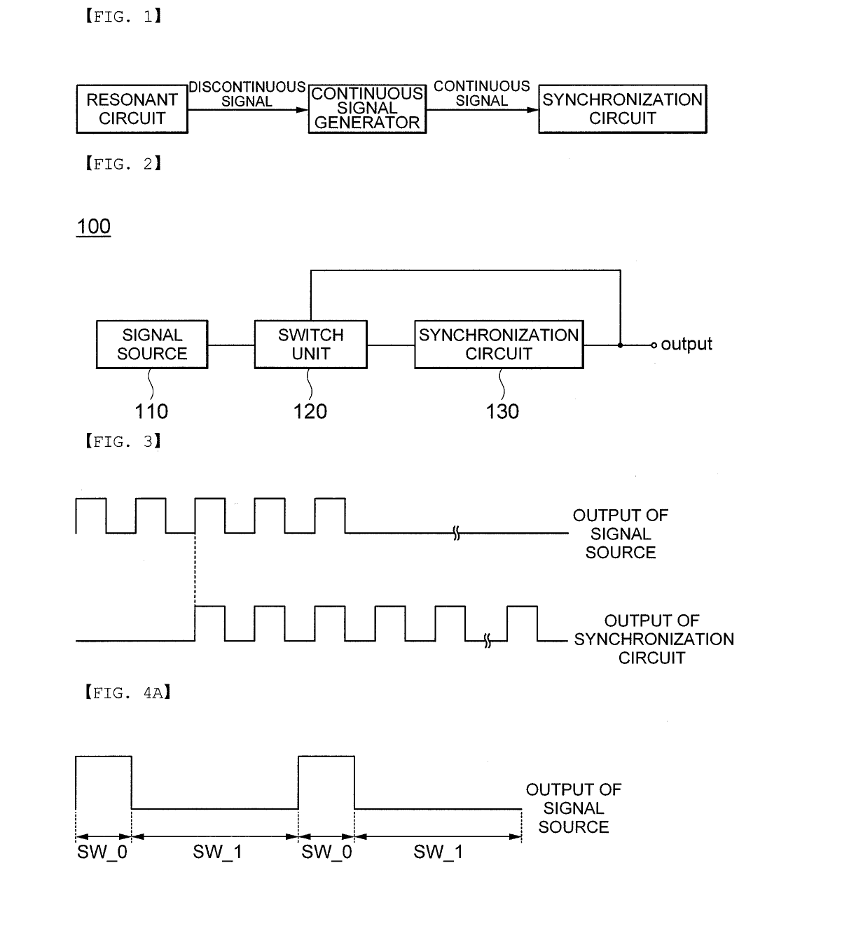

FIG. 1 is a conceptual block diagram of a continuous signal generator according to an exemplary embodiment of the present invention; and FIG. 2 is a specific block diagram of the continuous signal generator according to the exemplary embodiment of the present invention.

Referring to FIG. 1, a concept of the present invention is that a clock signal output from a resonant circuit is used as an input signal of a synchronization circuit. More specifically, a concept of the present invention is that when the clock signal output from the resonant circuit is a continuous signal, the clock signal is used as an input of the synchronization circuit, and when the clock signal output from the resonant circuit is a discontinuous signal, the discontinuous signal is converted into a continuous signal by a continuous signal generator and then used as an input of the synchronization circuit.

Referring to FIG. 2, a continuous signal generator 100 according to an exemplary embodiment of the present invention may include a synchronization circuit 130 generating a synchronized clock signal; a signal source 110 supplying a clock signal to the synchronization circuit 130; and a switch unit 120 connected between the synchronization circuit 130 and the signal source 110 and selectively switched so as to allow the clock signal output from the signal source 110 to be input to the synchronization circuit 130 or feed back a clock signal output from the synchronization circuit 130 to input the clock signal to the synchronization circuit 130. That is, the continuous signal generator of FIG. 1 may be implemented by the switch unit 120.

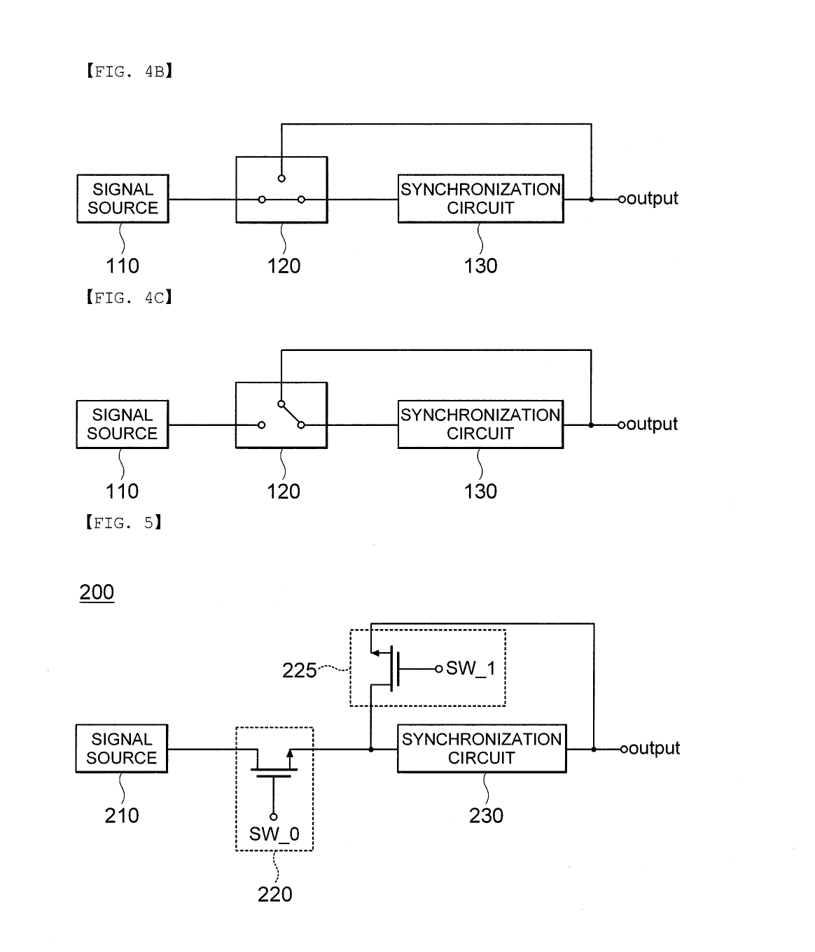

FIG. 3 is a diagram showing an output signal of a synchronization circuit according to the exemplary embodiment of the present invention for an output signal of a signal source.

The synchronization circuit 130 may be a synchronous mirror delay (SMD). The SMD, which is a kind of delay locked loop (DLL), is a synchronization circuit that may be fast locked.

The SDM (not shown) may generally include two delay blocks, one control block, an input buffer, and a clock driver. Here, the two delay blocks may include one forward delay array (FDA) and one backward delay array (BDA). In addition, the SMD may have a delay time corresponding to the sum d1+d2 of a delay time d1 of an input buffer and a delay time d2 of a clock driver. A delay time TdF (the sum of delay times of an NAND and an inverter) of a unit delay element of the FDA may be the same as a delay time TdB of a unit delay element of the BDA. An external signal having a period of Tclk may have a delay time corresponding to Tclk-d1-d2 in the FDA and also have a delay time corresponding to Tclk-d1-d2 in the BDA. Therefore, overall, a clock signal input from the outside may have a delay time corresponding to d1+(d1+d2)+(Tclk-d1-d2)+(Tclk-d1-d2)+d2=2Tclk. That is, overall, the synchronization of the clocks may be performed after two cycles as shown in FIG. 3.

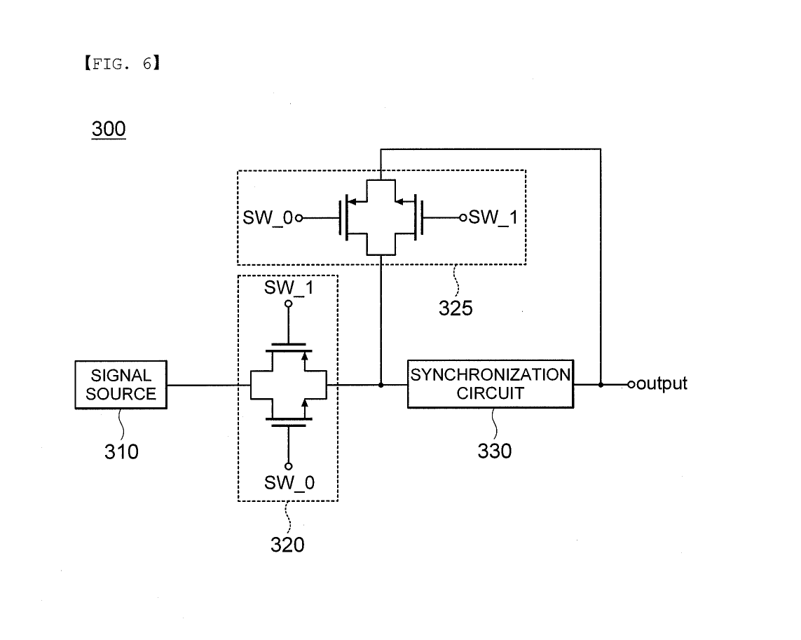

FIGS. 4A to 4C are operational block diagrams of the continuous signal generator according to a period of the output signal of the signal source.

The signal source 10 may be a MEMS resonator. Therefore, since the clock signal output from the signal source 110 may be a discontinuous signal as shown in FIG. 4A, the discontinuous signal may be converted into a continuous signal and then input to the synchronization circuit. Referring to FIG. 4A, a continuous signal, which is a signal in a period corresponding to SW_0, may be input and a discontinuous signal, which is a signal in a period corresponding to SW_1 may not be input, to the synchronization circuit 130.

Referring to FIG. 4B, in the clock signal of the signal source 110, in the case of the SW_0 period, the switch unit 120 may be switched so that the clock signal output from the signal source 110 becomes an input of the synchronization circuit 130.

However, referring to FIG. 4C, in the clock signal of the signal source 110, in the case of the SW_1 period, the clock signal output from the signal source 110 corresponds to a discontinuous signal, such that it may not be input to the synchronization circuit 130. Therefore, the switch unit 120 may be switched so that a clock signal output from the synchronization circuit 130 is fed back to again become an input of the synchronization circuit 130. In this case, the input of the discontinuous signal of the signal source 110 in the SW_1 period to the synchronization circuit 130 may be blocked by the switch unit 120, and the continuous signal, which is the output signal of the signal source 110 in the SW_0 period, may be fed back in the SW_1 period to be again input to the synchronization circuit 130.

Therefore, regardless of whether the clock signal of the signal source 110 is a continuous signal or a discontinuous signal, the continuous signal may be always input to the synchronization circuit 130 by the switching of the switch unit 120.

Meanwhile, when the SW_1 period ends, the switch unit 120 is switched so as to connect the signal source 110 and the synchronization circuit 130 to each other, thereby making it possible to allow the continuous signal of the signal source 110 to be input to the synchronization circuit 130. Therefore, noise of the clock signal may be accumulated due to the feedback. However, the clock signal of the signal source 110 is again used as the input signal of the synchronization circuit 130 by the switching of the switch unit 120, thereby making it possible to reduce the noise of the clock signal.

FIG. 5 is a diagram showing the continuous signal generator according to the exemplary embodiment of the present invention.

Referring to FIG. 5, the switch unit 120 may include a first switching element 220 connected between the signal source 210 and the synchronization circuit 230; and a second switching element 225 selectively switched with respect to the first switching element 220 and feeding back an output of the synchronization circuit 230 to again input the output to the synchronization circuit 230.

The first switching element 220 may be a first NMOS, and the second switching element 225 may be a second NMOS. An SW_0 clock signal may be applied to a gate of the first NMOS 220, and an SW_1 clock signal may be applied to a gate of the second NMOS 225. Here, when the SW_0 clock signal is high, the SW_1 clock signal is low, and when the SW_0 clock signal is low, the SW_1 clock is high.

When the SW_0 clock signal applied to the gate of the first NMOS 220 is high, the first NMOS 220 may become a turn-on state and the second NMOS 225 may become a turn-off state. Therefore, the clock signal of the signal source 210 may be input to the synchronization circuit 230, and a signal synchronized by the synchronization circuit 230 may be output.

When the SW_0 clock signal applied to the gate of the first NMOS 220 is low, the first NMOS 220 may become a turn-off state and the second NMOS 225 may become a turn-on state. Therefore, the clock signal of the signal source 210 may not be input to the synchronization circuit 230, and the second NMOS 225 may feed back an output signal of the synchronization circuit 230 to again input the output signal of the synchronization circuit 230 to the synchronization circuit 230, such that a signal synchronized by the synchronization circuit 230 may be output. That is, regardless of whether or not the clock signal of the signal source 210 is continuous and discontinuous, the output signal of the synchronization circuit 230 is fed back, thereby making it possible to always input the continuous signal to the synchronization circuit 230.

Meanwhile, the first switching element 220 may be a first PMOS, and the second switching element 225 may be a second PMOS. The SW_1 clock signal may be applied to a gate of the first PMOS 220, and the SW_0 clock signal may be applied to a gate of the second PMOS 225. Here, when the SW_0 clock signal is high, the SW_1 clock signal is low, and when the SW_0 clock signal is low, the SW_1 clock is high.

When the SW_1 clock signal applied to the gate of the first PMOS 220 is low, the first PMOS 220 may become a turn-on state and the second PMOS 225 may become a turn-off state. Therefore, the clock signal of the signal source 210 may be input to the synchronization circuit 230, and a signal synchronized by the synchronization circuit 230 may be output.

When the SW_1 clock signal applied to the gate of the first PMOS 220 is high, the first PMOS 220 may become a turn-off state and the second PMOS 225 may become a turn-on state. Therefore, the clock signal of the signal source 210 may not be input to the synchronization circuit 230, and the second PMOS 225 may feed back an output signal of the synchronization circuit 230 to again input the output signal of the synchronization circuit 230 to the synchronization circuit 230, such that a signal synchronized by the synchronization circuit 230 may be output. That is, regardless of whether or not the clock signal of the signal source 210 is continuous and discontinuous, the output signal of the synchronization circuit 230 is fed back, thereby making it possible to always input the continuous signal to the synchronization circuit 230.

FIG. 6 is a diagram showing a continuous signal generator according to another exemplary embodiment of the present invention.

Referring to FIG. 6, the first switching element may be a first transmission-gate 320, and the second switching element may be a second transmission-gate 325. The first transmission-gate 320 is a switching element in which a PMOS and an NMOS are coupled in parallel with each other and may be connected between the signal source 310 and the synchronization circuit 330. The second transmission-gate 325 is a switching element in which a PMOS and an NMOS are coupled and may be connected in parallel with the synchronization circuit 330.

When the SW_0 clock signal applied to a gate of the NMOS of the first transmission-gate 320 is high and the SW_1 clock signal applied to a gate of the PMOS thereof is low, the first transmission-gate 320 may become a turn-on state and the second transmission-gate 325 may become a turn-off state. That is, when the clock signal applied to the gate of the NMOS of the first transmission-gate 320 is high and the clock signal applied to the gate of the PMOS thereof is low, the clock signal applied to the gate of the NMOS of the second transmission-gate 325 is low and the clock signal applied to the gate of the PMOS thereof is high, such that the first transmission-gate 320 may become a turn-on state and the second transmission-gate 325 may become a turn-off state. Therefore, the clock signal of the signal source 310 may be input to the synchronization circuit 330, and a signal synchronized by the synchronization circuit 330 may be output.

On the other hand, when the SW_0 clock signal applied to the gate of the NMOS of the first transmission-gate 320 is low and the SW_1 clock signal applied to the gate of the PMOS thereof is high, the first transmission-gate 320 may become a turn-off state and the second transmission-gate 325 may become a turn-on state. That is, when the clock signal applied to the gate of the NMOS of the first transmission-gate 320 is low and the clock signal applied to the gate of the PMOS thereof is high, the clock signal applied to the gate of the NMOS of the second transmission-gate 325 is high and the clock signal applied to the gate of the PMOS thereof is low, such that the first transmission-gate 320 may become a turn-off state and the second transmission-gate 325 may become a turn-on state. Therefore, the clock signal of the signal source 310 may not be input to the synchronization circuit 330, and the second transmission-gate 325 may feed back an output signal of the synchronization circuit 330 to again input the output signal of the synchronization circuit 330 to the synchronization circuit 330, such that a signal synchronized by the synchronization circuit 330 may be output. That is, regardless of whether or not the clock signal of the signal source 310 is continuous and discontinuous, the output signal of the synchronization circuit 330 is fed back, thereby making it possible to always input the continuous signal to the synchronization circuit 330.

As set forth above, according to the exemplary embodiments of the present invention, in the case in which a discontinuous signal source is present in a system, the continuous signal may be input to the synchronization circuit without using an exterior oscillator or an exterior PLL.

In addition, the switching is performed with respect to the feedback and an oscillator lowering a Q-factor is not used, thereby making it possible to improve low noise characteristics.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A continuous signal generator comprising:
a synchronization circuit generating a synchronized clock signal;
a signal source supplying a clock signal to the synchronization circuit; and
a switch unit connected between the synchronization circuit and the signal source and selectively switched so as to allow the clock signal output from the signal source to be input to the synchronization circuit or feed back a clock signal output from the synchronization circuit to input the clock signal to the synchronization circuit.

2. The continuous signal generator according to claim 1, wherein the switch unit is switched so as to connect the signal source and the synchronization circuit to each other when the signal source outputs a continuous signal.

3. The continuous signal generator according to claim 2, wherein the switch unit is switched so as to disconnect the signal source and the synchronization circuit from each other and feed back the clock signal output from the synchronization circuit to input the clock signal output from the synchronization circuit to the synchronization circuit, when the signal source outputs a discontinuous signal.

4. The continuous signal generator according to claim 3, wherein the switch unit is switched so as to connect the signal source and the synchronization circuit to each other, thereby removing noise of the clock signal due to the feedback, when the signal source outputs the discontinuous signal and then outputs the continuous signal.

5. A continuous signal generator comprising:
a synchronization circuit generating a synchronized clock signal;
a signal source supplying a clock signal to the synchronization circuit;
a first switching element connected between the signal source and the synchronization circuit; and
a second switching element selectively switched with respect to the first switching element and feeding back an output of the synchronization circuit to again input the output to the synchronization circuit.

6. The continuous signal generator according to claim 5, wherein when the first switching element is turned on, the second switching element is turned off, and when the first switching element is turned off, the second switching element is turned on.

7. The continuous signal generator according to claim 6, wherein the first and second switching elements are NMOSs, when a clock signal applied to a gate of the first switching element is high, a clock signal applied to a gate of the second switching element is low, and when the clock signal applied to the gate of the first switching element is low, the clock signal applied to the gate of the second switching element is high.

8. The continuous signal generator according to claim 7, wherein the first and second switching elements are PMOSs, when the clock signal applied to the gate of the first switching element is high, the clock signal applied to the gate of the second switching element is low, and when the clock signal applied to the gate of the first switching element is low, the clock signal applied to the gate of the second switching element is high.

9. The continuous signal generator according to claim 8, wherein the first and second switching elements are transmission-gates in a form in which the PMOS and the NMOS are coupled in parallel with each other.

10. The continuous signal generator according to any one of claims 1 to 9, wherein the signal source is a MEMS resonator.

11. The continuous signal generator according to any one of claims 1 to 9, wherein the synchronization circuit is a synchronous mirror delay.
